(19) United States
(12) Patent Application Publication
(10) Pub. No.: US 2009/0124043 A1
(43) Pub. Date: May 14, 2009

(54) Method of manufacturing a package board

(75) Inventors: Won-Cheol Bae, Osan-si (KR); Young-Do Kweon, Seoul (KR); Doo-Hwan Lee, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/149,837

(22) Filed: May 8, 2008

(30) Foreign Application Priority Data
Nov. 13, 2007 (KR) 10-2007-0115551

(51) Int. Cl. H01L 21/52

(52) U.S. Cl. 438/106; 257/E21.5

(57) ABSTRACT

A method of manufacturing a package board is disclosed. The method is for manufacturing a package board that has a pad electrically connected with a component, and includes: forming an indentation, which is in correspondence with the pad, in one side of a first insulating layer; filling a metal paste in the indentation; mounting the component on the first insulating layer in correspondence with a location of the indentation; and hardening the metal paste. Using this method, damage to the component can be prevented during the forming of vias, as the component is mounted after filling paste in an indentation formed in an insulating layer.

### CROSS-REFERENCE TO RELATED APPLICATIONS

This application claims the benefit of Korean Patent Application No. 10-2007-0115551 filed with the Korean Intellectual Property Office on Nov. 13th, 2007, the disclosure of which is incorporated herein by reference in its entirety.

### BACKGROUND

1. Technical Field

The present invention relates to a method of manufacturing a package board.

2. Description of the Related Art

Recent trends have seen package manufacturing businesses and chip fabrication businesses actively developing methods for embedding active components within the substrate directly, in step with the demands for lighter, thinner, and more compact products. Each business is developing its own process for embedding active components of different sizes, and various attempts have been made regarding processes for embedding thin components.

In the case of manufacturing a component-embedded package board, a cavity method is generally used, an example of which is shown in FIG. 1 through FIG. 7. A brief description of such a method is as follows.

First of all, a cavity 2 may be bored in a core substrate 1, on which a pattern 3 may be formed, as shown in FIG. 1. The lower side of the cavity 2 may be covered by an adhesive tape 4 attached onto the lower side of the core substrate 1, as shown in FIG. 2. Then, a component 5 may be mounted, as shown in FIG. 3.

Afterwards, the component 5 may be covered by an insulating layer 6 stacked over the upper side of the core substrate 1, as shown in FIG. 4, and the adhesive tape 4 may be removed, as shown in FIG. 5. An insulating layer 7 may be stacked over the lower side of the core substrate 1, as shown in FIG. 6.

Next, vias 9 and circuit patterns 8 may be formed respectively in the insulating layers 6, 7, as shown in FIG. 7, so that a package board having -an embedded component 5 may be manufactured.

In the case of the related art, as laser processing may be used in forming the vias 9 that electrically connect the circuit patterns 8 to the component 5, the pads of the component 5 may be damaged, and defects may be incurred in the fine-lined circuits of the component 5.

In addition, since a core substrate 1 may be needed that is in correspondence with the thickness of the component 5, the overall thickness of the package board may be increased, which presents a disadvantage in implementing smaller size and lower thickness.

### SUMMARY

An aspect of the invention provides a method of manufacturing a package board, which prevents damage to the component during the forming of vias, and which enables the implementation of fine-pitch circuits.

Another aspect of the invention provides a method of manufacturing a package board that has a pad electrically connected with a component. The method includes: forming an indentation, which is in correspondence with the pad, in one side of a first insulating layer; filling a metal paste in the indentation; mounting the component on the first insulating layer in correspondence with a location of the indentation; and hardening the metal paste.

Forming the indentation may include: forming a pad pattern, which is in correspondence with the pad, on a side of a carrier; pressing the carrier onto the first insulating layer such that the pad pattern is transferred to the one side of the first insulating layer; and removing at least a portion of the pad pattern. Here, the removing may include forming an etching resist layer over the one side of the first insulating layer such that the pad pattern is exposed; and providing an etchant to the one side of the first insulating layer.

Also, a supporting layer may be stacked on other side of the first insulating layer before transferring the pad pattern.

The mounting can be preformed by a flip chip method, and the metal paste can be made of a material that contains copper (Cu) or silver (Ag).

A second insulating layer may be stacked on one side of the first insulating layer such that the component is covered, in which case a circuit pattern may be formed on the second insulating layer.

A via that penetrates the first insulating layer may be formed in correspondence with a location of the indentation.

Additional aspects and advantages of the present invention will be set forth in part in the description which follows, and in part will be obvious from the description, or may be learned by practice of the invention.

### BRIEF DESCRIPTION OF THE DRAWINGS

FIG. 1, FIG. 2, FIG. 3, FIG. 4, FIG. 5, FIG. 6, and FIG. 7 are cross-sectional views representing a flow diagram for a method of manufacturing a package board according to the related art.

FIG. 8 is a flowchart for a method of manufacturing a package board according to an aspect of the present invention.

FIG. 9, FIG. 10, FIG. 11, FIG. 12, FIG. 13, FIG. 14, FIG. 15, FIG. 16, FIG. 17, and FIG. 18 are cross-sectional views representing a flow diagram for a method of manufacturing a package board according to an aspect of the present invention.

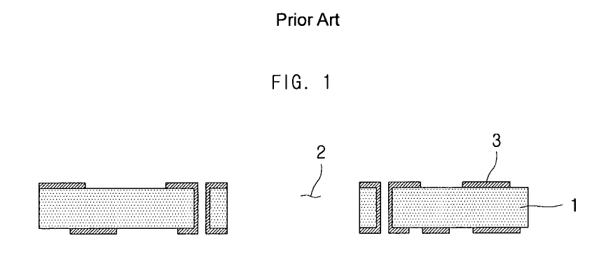

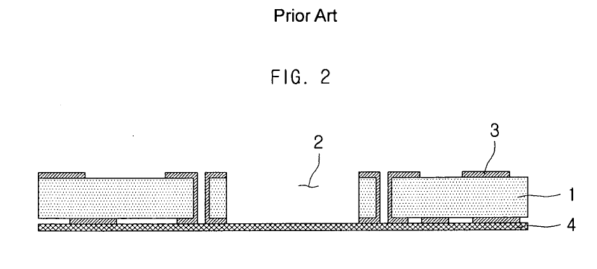

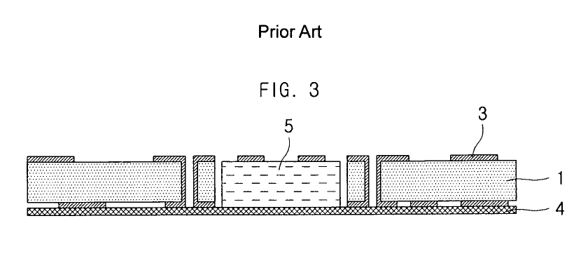

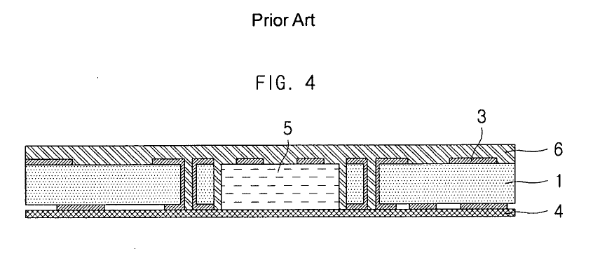

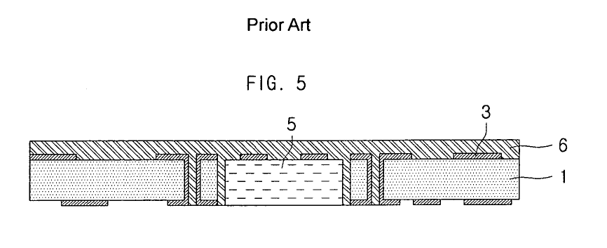

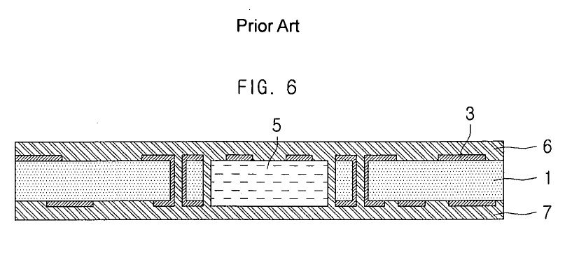

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first,” “second,” etc., may be used to describe various elements, such elements must not be limited to the above terms. The above terms are used only to distinguish one element from another.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

The method of manufacturing a package board according to certain embodiments of the invention will be described below in more detail with reference to the accompanying drawings. Those elements that are the same or are in correspondence are rendered the same reference numeral regardless of the figure number, and redundant explanations are omitted.

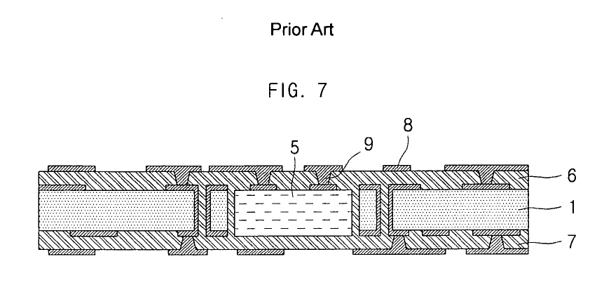

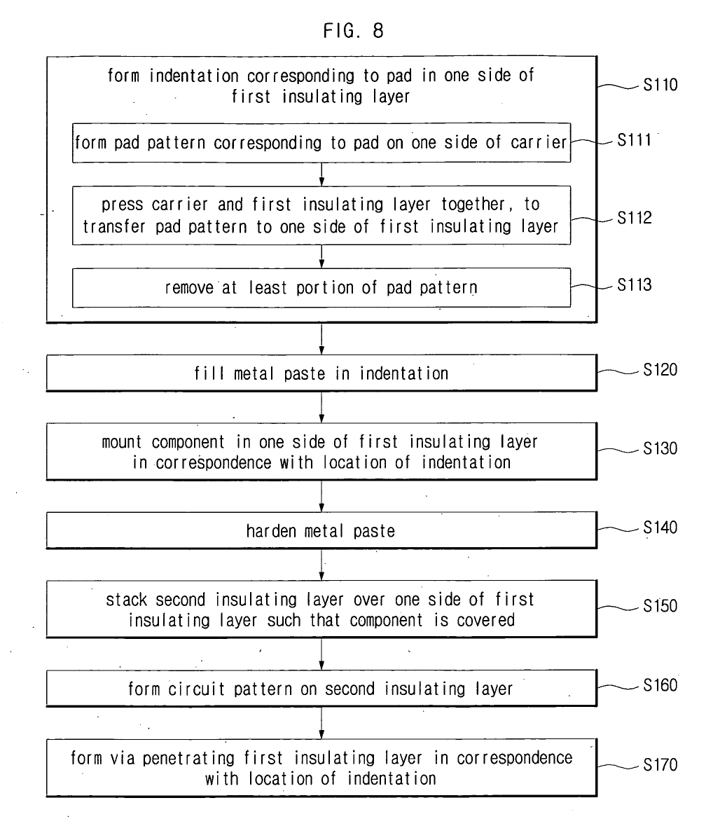

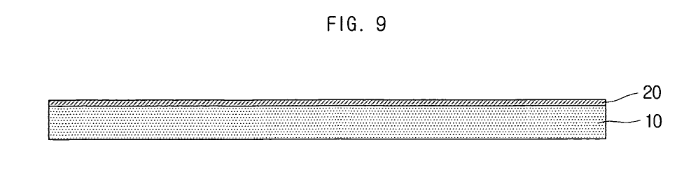

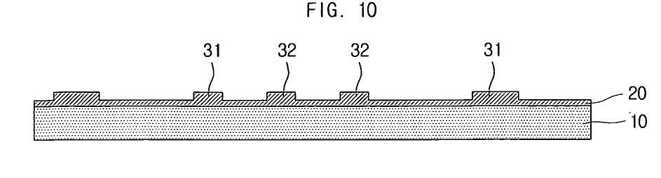

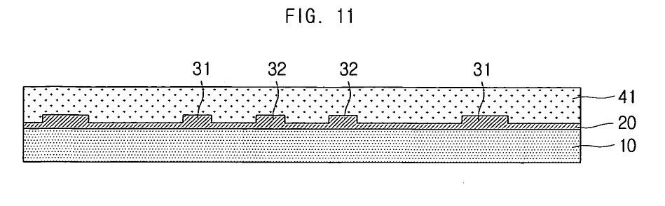

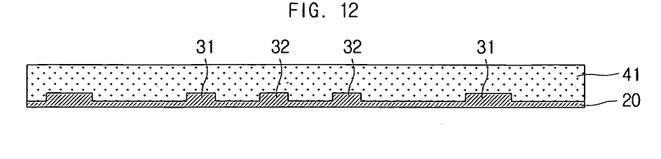

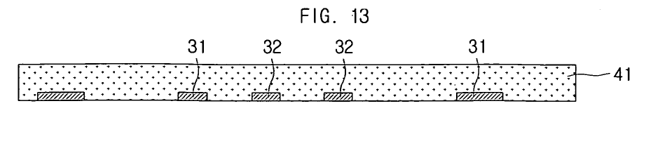

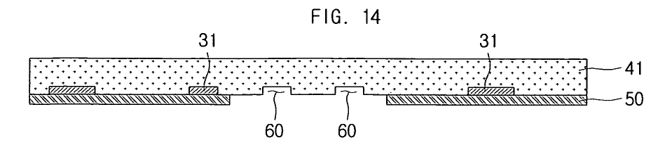

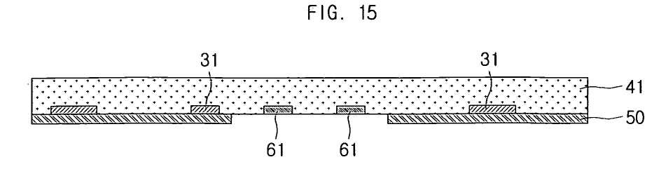

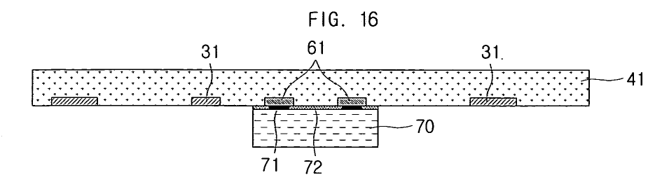

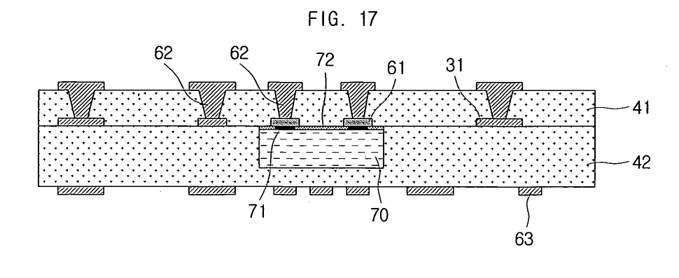

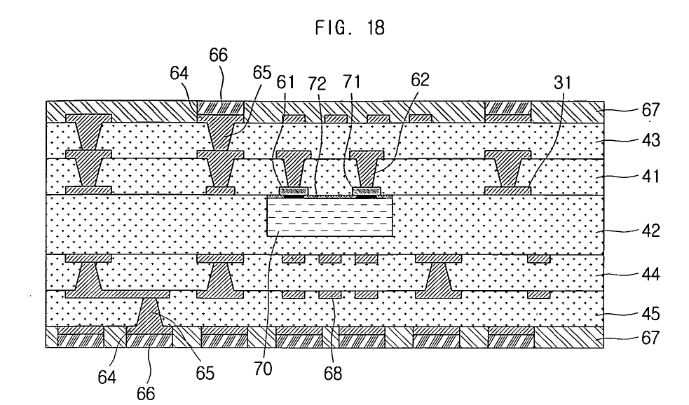

FIG. 8 is a flowchart for a method of manufacturing a package board according to an aspect of the present invention, and FIG. 9 through FIG. 18 are cross-sectional views representing a flow diagram for a method of manufacturing a package board according to an aspect of the present invention. In FIG. 9 through FIG. 18 are illustrated a carrier 10, a metal foil 20, a circuit pattern 31, a pad pattern 32, a first insulating layer 41, a second insulating layer 42, an etching resist layer 50, indentations 60, pads 61, vias 62, lands 64, plating layers 66, solder resists 67, a component 70, conductive bumps 71, and an underfill 72.

First, indentations 60 that are in correspondence with pads 61, may be formed in one side of a first insulating layer 41 (S110). This will be described in more detail as follows.

First, a pad pattern 32 that is in correspondence with the pads may be formed on one side of a carrier 10 (S111). The carrier 10 can be made of a resin or metal. In this particular embodiment, the carrier can be made of metal.

As shown in FIG. 9, a metal foil 20 may be formed over the upper side of the carrier 10 such that a pad pattern 32 is formed. The pad pattern 32 may be formed by performing electroplating, using the metal foil 20 as a seed layer. Also, a circuit pattern 31 may be formed while the pad pattern 32 is being formed. In the example shown in FIG. 10, the pad pattern 32 and the circuit pattern 31 can be formed on the upper side of the carrier 10.

While this particular embodiment is described with the pad pattern 32 formed by electroplating, the pad pattern 32 can also be formed without a seed layer, using an ink-jet method or a screen printing method.

Then, the carrier 10 may be pressed to the first insulating layer 41 such that the pad pattern is transferred to the first insulating layer (S112). That is, the upper side of the carrier 10 on which the pad pattern 32 is formed may be pressed into the first insulating layer 41, as in the example shown in FIG. 11, and the carrier 10 may afterwards be removed, as shown in FIG. 12. Then, the metal foil 20 may be removed, so that the pad pattern 32 formed on the carrier 10 may be transferred to and buried in the first insulating layer 41.

The carrier may be removed by peeling, if the carrier is a type of film. Also, the carrier may be removed using a chemical method such as wet etching, if the carrier is made of metal.

After the pad pattern 32 is transferred to the first insulating layer 41, at least a portion of the pad pattern may be removed, as in the example shown in FIG. 14 (S113). If a circuit pattern 31 and the pad pattern are formed on the first insulating layer 41, an etching resist layer 50 exposing only the pad pattern 32 may be formed over the first insulating layer 41, and an etchant may be provided such that the pad pattern 32 is removed selectively. Here, all or a portion of the pad pattern 32 buried in the first insulating layer 41 may be removed.

While the above description illustrates a method of forming the indentations 60 by transferring and removing the pad pattern 32 using a carrier 10, mechanical methods such as laser processing or chemical methods are also possible in forming the indentations 60.

After the indentations 60 are formed in correspondence with the pads, a metal paste may be filled in the indentations 60, as shown in FIG. 15 (S120), and a component 70 may be mounted in correspondence with the locations of the indentations, as shown in FIG. 16 (S130). Then, the metal paste may be hardened (S140). The metal paste may later be hardened, so as to serve as pads that are electrically connected with the electrodes of the component 70. As such, according to this embodiment, the conductive bumps 71 and the pads may be joined easily and firmly, by filling unhardened metal paste in the indentations 60 and mounting the component 70 thereon.

Copper (Cu) or silver (Ag), which are high in conductivity, can be used for the metal paste filled in the indentations 60. Of course, various other conductive materials may also be employed.

Next, a second insulating layer 42 may be stacked over one side of the first insulating layer 41 such that the component 70 is covered, as in the example shown in FIG. 17 (S150), and a circuit pattern 31 may be formed on the second insulating layer 42 (S160). As the second insulating layer 42 is stacked over the first insulating layer 41, the component 70 can be embedded in the board.

Vias 62 that penetrate the first insulating layer 41 may be formed in correspondence with the locations of the indentations 60 (S170). Since the vias 62 that penetrate the first insulating layer 41 may be formed after the pads 61 formed on the lower side of the first insulating layer 41 are connected with the electrodes of the component 70, the risk that the electrodes (not shown) of the component 70 may be exposed and damaged during the processing of the vias 62 may be reduced. Moreover, since there is no need for separate copper (Cu) posts, redistribution costs may be reduced.

Afterwards, additional insulating layers 43, 44, 45 may be stacked over the first and second insulating layers 41, 42, and additional circuit patterns 68 and vias 65 may be formed, to manufacture a multi-layered package board, such as that shown in FIG. 18. Solder resists 67 may be formed on the outermost layers, and plating layers 66 may be formed over the exposed portions, such as the lands 64.

According to certain aspects of the invention as set forth above, by mounting a component after filling paste in an indentation formed in an insulating layer, damage to the component can be prevented during the forming of vias.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

1. A method of manufacturing a package board having a pad electrically connected with a component, the method comprising:
forming an indentation in one side of a first insulating layer, the indentation being in correspondence with the pad;
filling a metal paste in the indentation;
mounting the component on the first insulating layer by a flip chip method in correspondence with a location of the indentation filled with the metal paste;
hardening the metal; and
forming a via penetrating the first insulating layer in correspondence with a location of the indentation after the metal paste has hardened.

2. The method of claim 1, wherein the forming of the indentation comprises:
forming a pad pattern on one side of a carrier, the pad pattern being in correspondence with the pad;
transferring the pad pattern to the one side of the first insulating layer by pressing the carrier onto the first insulating layer; and
removing at least a portion of the pad pattern.

3. The method of claim 2, wherein the removing comprises:
forming an etching resist layer over the one side of the first insulating layer such that the pad pattern is exposed; and
providing an etchant to the one side of the first insulating layer.

4. The method of claim 2, further comprising, before the transferring of the pad pattern:
stacking a support layer on the other side of the first insulating layer.

5. (canceled)

6. The method of claim 1, wherein the metal paste is made of a material containing copper (Cu) or silver (Ag).

7. The method of claim 1, further comprising:
stacking a second insulating layer on the one side of the first insulating layer such that the component is covered; and
forming a circuit pattern on the second insulating layer.

8. (canceled)
